(19) United States
(12) Patent Application Publication
(10) Pub. No.: US 2026/0114214 A1
(43) Pub. Date: Apr. 23, 2026

(54) SUBSTRATE CLEANING APPARATUS AND SUBSTRATE PROCESSING APPARATUS INCLUDING THE SAME

(71) Applicant: Samsung Electronics Co., Ltd., Suwon-si (KR)

(72) Inventors: Jae Young BAE, Suwon-si (KR); Donghoon KWON, Suwon-si (KR)

(21) Appl. No.: 19/336,298

(22) Filed: Sep. 22, 2025

(30) Foreign Application Priority Data
Oct. 18, 2024 (KR) 10-2024-0142952

(51) Int. Cl. H01L 21/67; B03C 1/033; B03C 1/30; B24B 57/02

(52) U.S. Cl. CPC H10P 72/0414; B03C 1/0335; B03C 1/30; B24B 57/02; B03C 2201/18

(57) ABSTRACT

Disclosed are substrate cleaning apparatuses and substrate processing apparatuses. The substrate cleaning apparatus comprises a stage that supports a substrate and an electromagnetic module on the stage. The electromagnetic module comprises an electromagnetic coil in the electromagnetic module. The electromagnetic module provides a first outlet and a second outlet on a bottom surface of the electromagnetic module. The electromagnetic coil is configured to generate a magnetic field on the substrate.

### CROSS-REFERENCE TO RELATED APPLICATION

This application claims priority under 35 U.S.C. § 119 to Korean Patent Application No. 10-2024-0142952 filed on Oct. 18, 2024, in the Korean Intellectual Property Office, the disclosure of which is hereby incorporated by reference in its entirety.

### BACKGROUND

The present inventive concepts relate to a substrate cleaning apparatus and a substrate processing apparatus including the same, and more particularly, to a substrate cleaning apparatus configured to use a magnetic field to remove contaminant particles on a substrate and a substrate processing apparatus including the same.

Various processes may be performed to fabricate a semiconductor device. For example, a substrate may undergo a photolithography process, an etching process, and a deposition process in fabricating a semiconductor device. It may be required that a surface of the substrate be planarized prior to each process. A polishing process may be executed on the substrate. The polishing process may be conducted in various ways. For example, a chemical mechanical polishing (CMP) process may be used to planarize the substrate. After the chemical mechanical polishing process, physical and/or chemical methods may be utilized to clean a surface of the substrate.

### SUMMARY

Some embodiments of the present inventive concepts provide a substrate cleaning apparatus configured to use a magnetic field to remove contaminant particles on a substrate and a substrate processing apparatus including the same.

The objects of the present inventive concepts are not limited to those mentioned above, and other objects which have not been mentioned above will be clearly understood to those skilled in the art from the following description.

According to some embodiments of the present inventive concepts, a substrate cleaning apparatus may comprise: a stage that supports a substrate; and an electromagnetic module on the stage. The electromagnetic module may comprise an electromagnetic coil in the electromagnetic module. The electromagnetic module may provide a first outlet and a second outlet on a bottom surface of the electromagnetic module. The electromagnetic coil may be configured to generate a magnetic field on the substrate.

According to some embodiments of the present inventive concepts, a substrate cleaning apparatus may comprise: a stage that supports a substrate; an electromagnetic module on the stage; a liquid supply unit that provides a treatment solution; and a deionized water supply unit that provides deionized water. The electromagnetic module may be configured to generate a magnetic field on the substrate. The treatment solution may comprise a magnetic material that has movement caused by the magnetic field.

According to some embodiments of the present inventive concepts, a substrate processing apparatus may comprise: a polishing section that uses a polishing pad to polish one surface of a substrate; and a cleaning section that cleans the substrate. The cleaning section may comprise: a stage that supports the substrate; an electromagnetic module on the stage; a liquid supply unit that provides a treatment solution onto the substrate; and a deionized water supply unit that provides deionized water onto the substrate. The electromagnetic module may be configured to generate a magnetic field on the substrate.

### BRIEF DESCRIPTION OF DRAWINGS

FIG. 1 illustrates a perspective view showing a substrate cleaning apparatus according to some example embodiments of the present inventive concepts.

FIG. 2 illustrates a plan view showing an electromagnetic module of a substrate cleaning apparatus according to some example embodiments of the present inventive concepts.

FIG. 3 illustrates a bottom view showing an electromagnetic module of a substrate cleaning apparatus according to some example embodiments of the present inventive concepts.

FIG. 4 illustrates a cross-sectional view taken along line A-A′ of FIG. 1, showing a substrate cleaning apparatus according to some example embodiments of the present inventive concepts.

FIG. 5 illustrates an enlarged view of section P depicted in FIG. 4, showing a principle of removing contaminant particles on a substrate according to some example embodiments of the present inventive concepts.

FIG. 6 illustrates a cross-sectional view taken along line A-A′ of FIG. 1, showing a substrate cleaning apparatus according to some example embodiments of the present inventive concepts.

FIGS. 7 and 8 illustrate bottom views showing an electromagnetic module of a substrate cleaning apparatus according to some example embodiments of the present inventive concepts.

FIG. 9 illustrates a plan view showing an electromagnetic module of a substrate cleaning apparatus according to some example embodiments of the present inventive concepts.

FIG. 10 illustrates a cross-sectional view taken along line A-A′ of FIG. 1, showing a substrate cleaning apparatus according to some example embodiments of the present inventive concepts.

FIG. 11 illustrates a perspective view showing a substrate cleaning apparatus according to some example embodiments of the present inventive concepts.

FIG. 12 illustrates a plan view showing a substrate cleaning apparatus according to some example embodiments of the present inventive concepts.

FIG. 13 illustrates a perspective view showing a substrate cleaning apparatus according to some example embodiments of the present inventive concepts.

FIG. 14 illustrates a plan view showing a substrate cleaning apparatus according to some example embodiments of the present inventive concepts.

FIG. 15 illustrates a perspective view showing a substrate processing apparatus according to some example embodiments of the present inventive concepts.

FIGS. 16 to 20 illustrate diagrams showing a substrate processing method according to some example embodiments of the present inventive concepts.

### DETAILED DESCRIPTION OF EMBODIMENTS

The following will now describe some embodiments of the present inventive concepts with reference to the accompanying drawings. Like reference numerals refer to like components throughout the description.

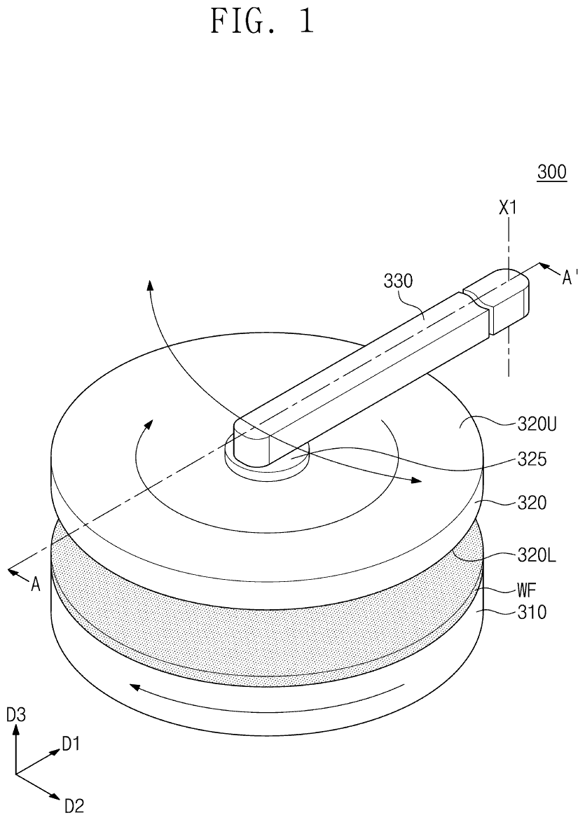

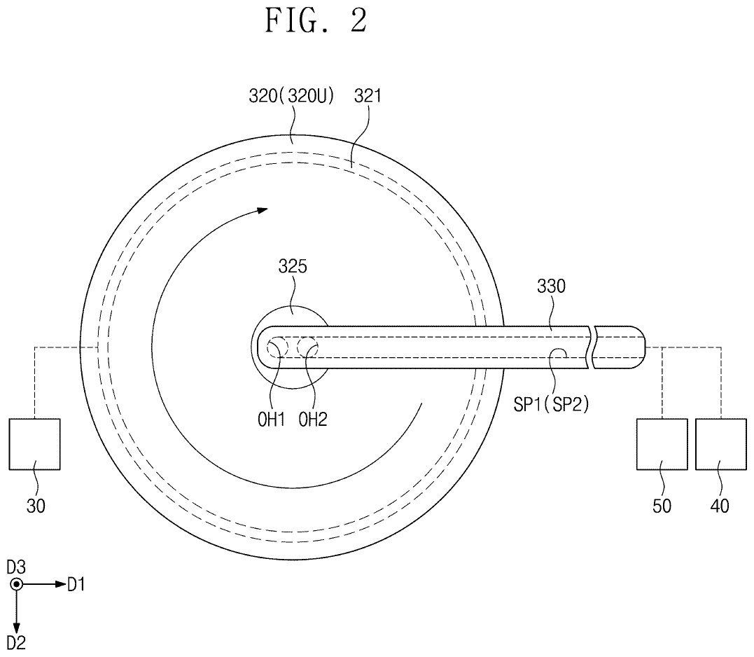

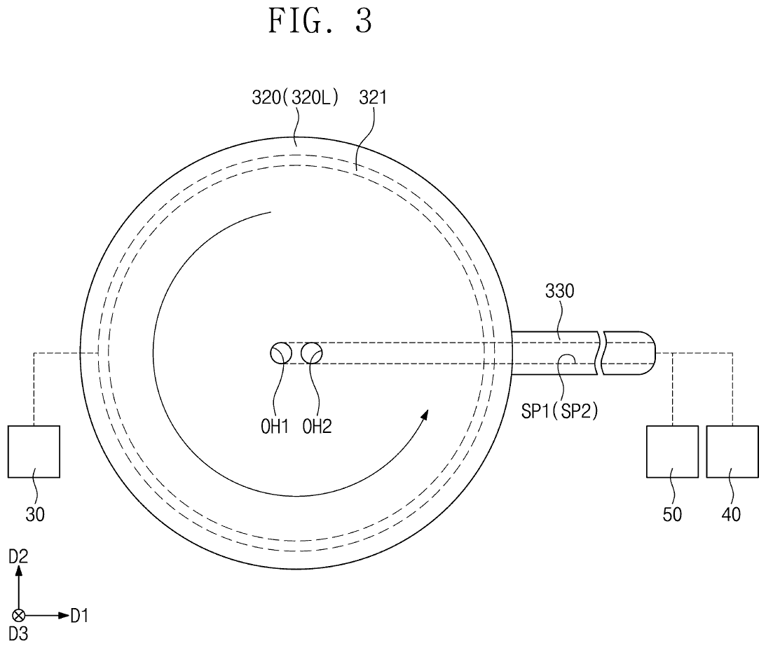

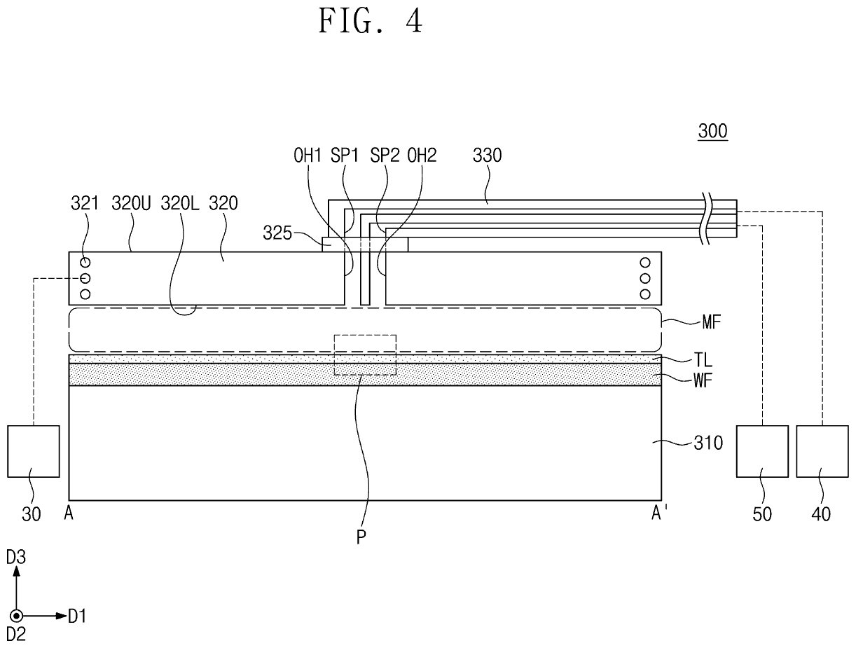

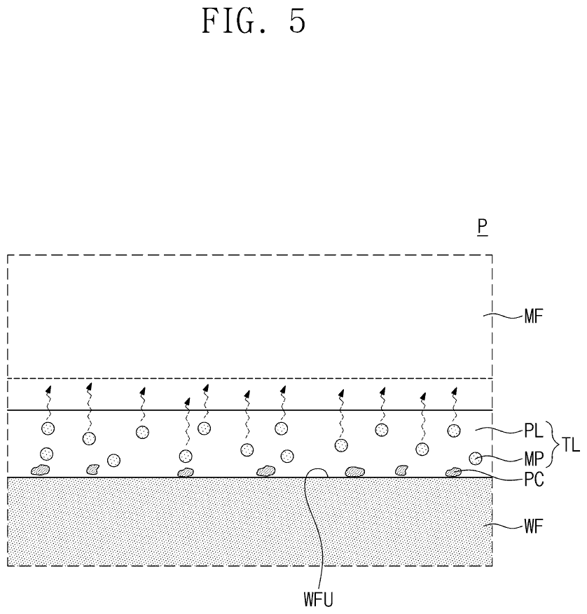

FIG. 1 illustrates a perspective view showing a substrate cleaning apparatus according to some example embodiments of the present inventive concepts. FIG. 2 illustrates a plan view showing an electromagnetic module of a substrate cleaning apparatus according to some example embodiments of the present inventive concepts. FIG. 3 illustrates a bottom view showing an electromagnetic module of a substrate cleaning apparatus according to some example embodiments of the present inventive concepts. FIG. 4 illustrates a cross-sectional view taken along line A-A′ of FIG. 1, showing a substrate cleaning apparatus according to some example embodiments of the present inventive concepts. FIG. 5 illustrates an enlarged view of section P depicted in FIG. 4, showing a principle of removing contaminant particles on a substrate according to some example embodiments of the present inventive concepts.

Referring to FIGS. 1 to 4, a substrate cleaning apparatus 300 may be provided. According to some embodiments of the present inventive concepts, the substrate cleaning apparatus 300 may be a device for cleaning a surface of a substrate WF. For example, the substrate cleaning apparatus 300 may remove contaminant particles present on the surface of the substrate WF. In this description, the term “substrate” may mean a silicon wafer, but the present inventive concepts are not limited thereto. The substrate cleaning apparatus 300 may include a stage 310, an electromagnetic module 320, and a first support member 330.

The stage 310 may be disposed in a lower portion of the substrate cleaning apparatus 300. The stage 310 may have a disk shape or a cylindrical shape. When viewed in plan, the stage 310 may have a diameter substantially the same as or greater than that of the substrate WF. The stage 310 may use a vacuum pressure to support the substrate WF on a top surface thereof. For example, the stage 310 may have a porous structure exposed on the top surface thereof, but the present inventive concepts are not limited thereto. The stage 310 may be configured to rotate in a clockwise or counterclockwise direction on a plane defined by a first direction D1 and a second direction D2. For example, the substrate WF may be fixed on the stage 310 and may rotate in a clockwise or counterclockwise direction along with the stage 310.

The first direction D1 and the second direction D2 may intersect each other. A direction parallel to a plane defined by the first direction D1 and the second direction D2 may be called a horizontal direction. A third direction D3 may intersect the first direction D1 and the second direction D2. The third direction D3 may be perpendicular to an upper surface of the stage 310. The third direction D3 may be called a vertical direction. For example, the first, second, and third directions D1, D2, and D3 may be orthogonal to each other.

The electromagnetic module 320 may be disposed in an upper portion of the substrate cleaning apparatus 300. The electromagnetic module 320 may be positioned on the stage 310. The electromagnetic module 320 may be spaced apart in a vertical direction (for example, the third direction D3) from the stage 310. The electromagnetic module 320 may have a disk shape. When viewed in plan, the electromagnetic module 320 may have a diameter substantially the same as that of the stage 310, but the present inventive concepts are not limited thereto. The electromagnetic module 320 may have a top surface 320U and a bottom surface 320L opposite to the top surface 320U. The bottom surface 320L of the electromagnetic module 320 may be directed toward the stage 310 and the substrate WF. The top surface 320U of the electromagnetic module 320 may be directed toward the first support member 330 which will be discussed below. For example, the top surface 320U of the electromagnetic module 320 may face the first support member 330.

The electromagnetic module 320 may include an electromagnetic coil 321 therein. When viewed in plan, the electromagnetic coil 321 may have a ring shape adjacent to an outer lateral surface of the electromagnetic module 320. In addition, the electromagnetic coil 321 may be provided in a spiral shape. The electromagnetic coil 321 may be electrically connected to a power supply device 30. The power supply device 30 may provide the electromagnetic coil 321 with current. The electromagnetic coil 321 may use the current supplied from the power supply device 30 to generate a magnetic field MF on the substrate WF.

The electromagnetic module 320 may provide a first outlet OH1 and a second outlet OH2 on the bottom surface 320L thereof. For example, the first outlet OH1 and the second outlet OH2 may be open on the bottom surface 320L of the electromagnetic module 320. The first outlet OH1 and the second outlet OH2 may be positioned on a central portion of the electromagnetic module 320. The first outlet OH1 and the second outlet OH2 may be spaced apart from each other in a horizontal direction (e.g., the first direction D1 and the second direction D2). When viewed in plan, each of the first outlet OH1 and the second outlet OH2 may have a circular shape, but the present inventive concepts are not limited thereto. Each of the first outlet OH1 and the second outlet OH2 may extend from the bottom surface 320L of the electromagnetic module 320 toward the top surface 320U of the electromagnetic module 320. For example, each of the first outlet OH1 and the second outlet OH2 may penetrate the electromagnetic module 320. According to some embodiments of the present inventive concepts, a treatment solution may be provided through the first outlet OH1 onto the substrate WF, and deionized water may be provided through the second outlet OH2 onto the substrate WF.

The first support member 330 may be positioned on the electromagnetic module 320. For example, the first support member 330 may have opposite ends in the form extended lengthwise in the first direction D1. One of the opposite ends of the first support member 330 may be combined with the electromagnetic module 320. A first axis X1 may penetrate the other of the opposite ends of the first support member 330. The first axis X1 may be parallel to the third direction D3. The first support member 330 may be configured to move in a horizontal direction about the first axis X1. For example, the first support member 330 may be configured to move in a horizontal direction (e.g., a direction parallel to a plane defined by the first direction D1 and the second direction D2). Thus, the electromagnetic module 320 combined with the first support member 330 may also move in a horizontal direction.

The first support member 330 may provide a first supply line SP1 and a second supply line SP2 therein. The first supply line SP1 may be connected to a liquid supply device 40. The liquid supply device 40 may include a pipeline connected to the first supply line SP1 and a storage that stores a treatment solution. For example, the liquid supply device 40 may be configured to provide the treatment solution through the first supply line SP1 onto the substrate WF. The second supply line SP2 may be connected to a deionized water (DIW) supply device 50. The DIW supply device 50 may include a pipeline connected to the second supply line SP2 and a storage that stores deionized water. For example, the DIW supply device 50 may be configured to provide the deionized water through the second supply line SP2 onto the substrate WF. The first supply line SP1 and the second supply line SP2 may overlap in the third direction D3. For example, the first supply line SP1 may overlap the second supply line SP2 along the first axis X1 of the first support member 330.

According to some embodiments of the present inventive concepts, the substrate cleaning apparatus 300 may further include a rotating device 325. The rotating device 325 may be positioned between the electromagnetic module 320 and the first support member 330. The rotating device 325 may connect the electromagnetic module 320 and the first support member 330 to each other. The rotating device 325 may cause the electromagnetic module 320 to be configured to rotate in a clockwise or counterclockwise direction on a plane defined by the first direction D1 and the second direction D2. For example, the rotating device 325 may perform a rotational motion through the rotating device 325, while moving in a horizontal direction by the first support member 330. In this case, a magnetic field generated from the electromagnetic coil 321 of the electromagnetic module 320 may be a rotating magnetic field. For example, the rotating device 325 may include a spindle.

Referring to FIGS. 4 and 5, a treatment layer TL may be provided on the substrate WF. The treatment layer TL may cover a top surface WFU of the substrate WF. The treatment layer TL may be in contact with the top surface WFU of the substrate WF. The treatment layer TL may include magnetic particles MP and a polymeric layer PL. For example, the treatment layer TL may be a polymeric material containing the magnetic particles MP. The magnetic particles MP may be uniformly distributed in the polymeric layer PL. For example, the magnetic particles MP may include iron oxide. According to some embodiments, a liquid-state treatment solution may be spin-coated on the top surface WFU of the substrate WF, and then the liquid-state treatment solution may be cured to form the treatment layer TL.

Contaminant particles PC may be present on the top surface WFU of the substrate WF. For example, the contaminant particles PC may be byproducts produced by a polishing process of the substrate WF. The treatment layer TL may cover the top surface WFU of the substrate WF, and may also cover the contaminant particles PC on the top surface WFU of the substrate WF. Therefore, the contaminant particles PC may be in contact with and attached to the polymeric layer PL of the treatment layer TL.

According to some embodiments of the present inventive concepts, the magnetic particles MP may have movement caused by a magnetic field MF generated from the electromagnetic coil 321 of the electromagnetic module 320. For example, the magnetic field MF generated on the substrate WF may compel the magnetic particles MP to move away from the top surface WFU of the substrate WF. For example, the magnetic particles MP may exhibit movement in a vertical direction (e.g., the third direction D3). The movement of the magnetic particles MP may produce cracks inside the polymeric layer PL. It may thus be possible to easily remove the treatment layer TL on the substrate WF. Accordingly, the contaminant particles PC on the top surface WFU of the substrate WF may be removed along with the treatment layer TL.

According to some embodiments of the present inventive concepts, the magnetic field MF generated from the electromagnetic coil 321 of the electromagnetic module 320 may be a rotating magnetic field. In this case, the magnetic particles MP may further exhibit oscillating movement in a horizontal direction due to the magnetic field MF. The oscillating movement in a horizontal direction of the magnetic particles MP may facilitate generation of cracks inside the polymeric layer PL.

According to some embodiments of the present inventive concepts, the polymeric layer PL may include PANiCNQ or poly(aniline-co-naphthoquinone) having magnetic properties. In addition, the contaminant particles PC may have magnetic properties due to the magnetic field MF generated from the electromagnetic coil 321 of the electromagnetic module 320. Thus, a magnetic force may be produced between the contaminant particles PC and the polymeric layer PL. The contaminant particles PC and the polymeric layer PL may have increased adhesion due to the magnetic force produced therebetween. Therefore, the contaminant particles PC may be completely removed along with the treatment layer TL, and thus the contaminant particles PC may not remain on the top surface WFU of the substrate WF.

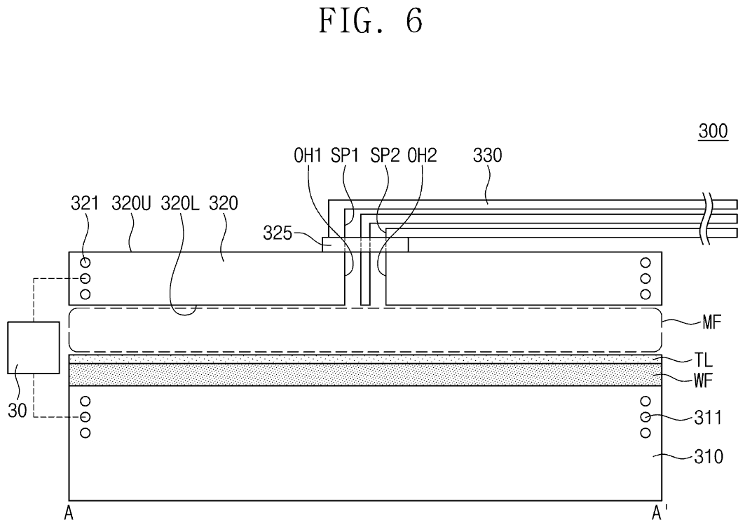

FIG. 6 illustrates a cross-sectional view taken along line A-A′ of FIG. 1, showing a substrate cleaning apparatus according to some example embodiments of the present inventive concepts.

For convenience of description, explanation of components substantially the same as those discussed with reference to FIGS. 1 to 4 will be omitted, and a difference thereof will be discussed in detail.

Referring to FIG. 6, the stage 310 of the substrate cleaning apparatus 300 may further include a lower electromagnetic coil 311 therein. Thus, the substrate WF may be positioned between the electromagnetic coil 321 of the electromagnetic module 320 and the lower electromagnetic coil 311 of the stage 310.

The lower electromagnetic coil 311 may have a structure substantially the same as that of the electromagnetic coil 321. For example, when viewed in plan, the lower electromagnetic coil 311 may have a ring shape adjacent to an outer lateral surface of the stage 310. In addition, the lower electromagnetic coil 311 may be provided in a spiral shape. The lower electromagnetic coil 311 may be electrically connected to the power supply device 30. The power supply device 30 may provide current to each of the electromagnetic coil 321 and the lower electromagnetic coil 311. The electromagnetic coil 321 and the lower electromagnetic coil 311 may each use the current supplied from the power supply device 30 to generate a magnetic field MF on the substrate WF.

Each of the stage 310 and the electromagnetic module 320 may be configured to rotate in a clockwise or counterclockwise direction on a plane defined by the first direction D1 and the second direction D2. The electromagnetic coil 321 inside the electromagnetic module 320 may rotate in a clockwise or counterclockwise direction along with the electromagnetic module 320. In addition, the lower electromagnetic coil 311 in the stage 310 may rotate in a clockwise or counterclockwise direction along with the stage 310. The electromagnetic coil 321 and the lower electromagnetic coil 311 may rotate together while facing each other. For example, the electromagnetic coil 321 and the lower electromagnetic coil 311 may constitute a Helmholtz coil. Thus, the magnetic field MF may be more uniformly generated on the substrate WF. It may thus be possible to easily remove the treatment layer TL on the surface of the substrate WF.

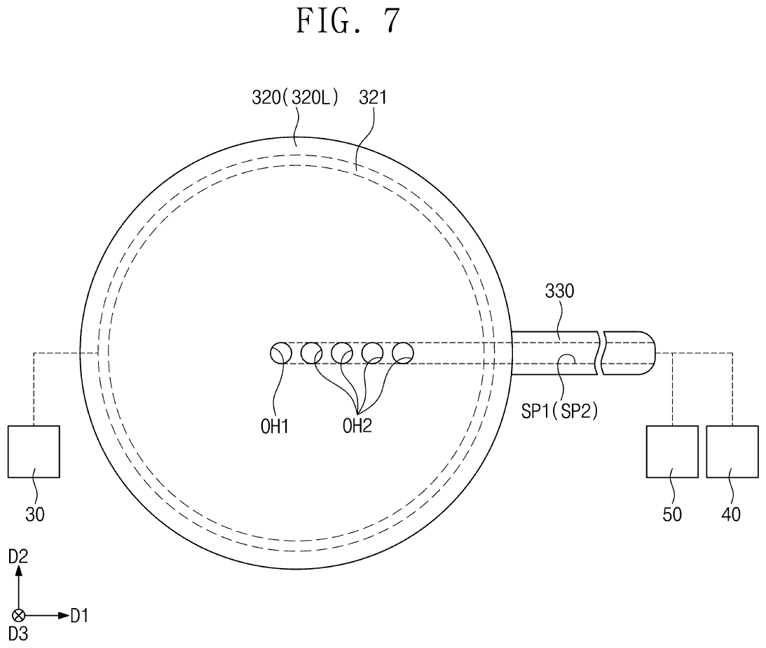

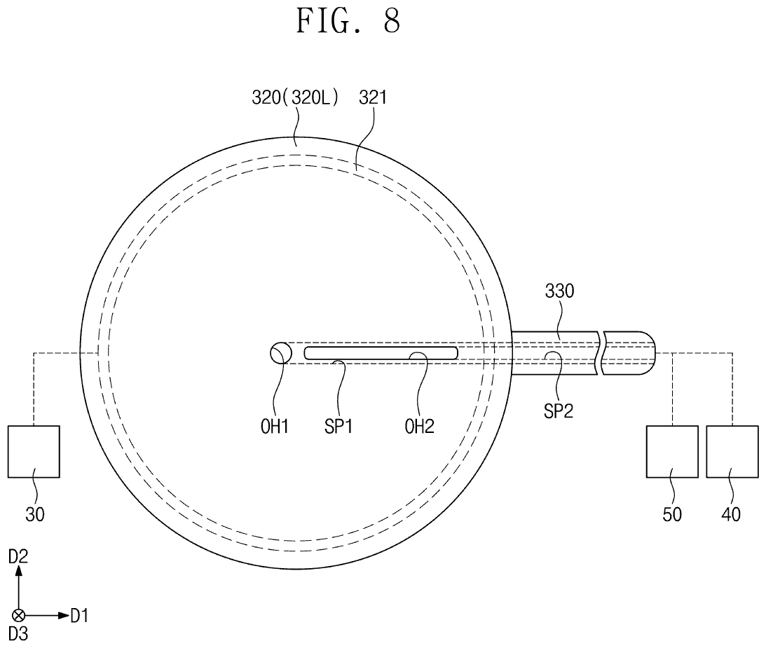

FIGS. 7 and 8 illustrate bottom views showing an electromagnetic module of a substrate cleaning apparatus according to some example embodiments of the present inventive concepts.

For convenience of description, explanation of components substantially the same as those discussed with reference to FIGS. 1 to 4 will be omitted, and a difference thereof will be discussed in detail.

Referring to FIG. 7, the electromagnetic module 320 may provide a single first outlet OH1 and a plurality of second outlets OH2 on the bottom surface 320L thereof. When viewed in plan, the first outlet OH1 and the plurality of second outlets OH2 may each have a circular shape, but the present inventive concepts are not limited thereto. The first outlet OH1 and the plurality of second outlets OH2 may be spaced apart from each other. The plurality of second outlets OH2 may be spaced apart from each other along the first direction D1. The first outlet OH1 and the plurality of second outlets OH2 may be aligned with each other along a horizontal direction.

The first outlet OH1 may be connected to the first supply line SP1 in the first support member 330, thereby providing a treatment solution onto the substrate WF of FIG. 4. Each of the plurality of second outlets OH2 may be connected to the second supply line SP2 in the first support member 330, thereby providing deionized water onto the substrate WF of FIG. 4. For example, the deionized water may be simultaneously provided through the plurality of second outlets OH2 onto the substrate WF. Thus, a large amount of deionized water may be widely provided on the substrate WF. Therefore, a treatment layer may be promptly removed in a substrate processing method which will be discussed below.

According to some embodiments, the rotating device 325 may not be provided between the electromagnetic module 320 and the first support member 330 discussed with reference to FIGS. 1 to 4. For example, the electromagnetic module 320 may not rotate in a clockwise or counterclockwise direction on a plane defined by the first direction D1 and the second direction D2.

Referring to FIG. 8, the electromagnetic module 320 may provide a first outlet OH1 and a second outlet OH2 spaced apart from each other on the bottom surface 320L thereof. When viewed in plan, the first outlet OH1 may have a circular shape. When viewed in plan, the second outlet OH2 may have a shape that extends lengthwise in the first direction D1. For example, the second outlet OH2 may have a slit shape that extends in one direction. The first outlet OH1 and the second outlet OH2 may be aligned with one another along a horizontal direction. In FIG. 8, a width in the horizontal direction of the second outlet OH2 may be greater than a width in the same horizontal direction of the first outlet OH1.

The DIW supply device 50 may provide deionized water onto the substrate WF of FIG. 4 through the second outlet OH2 having a shape that extends in the first direction D1. Like in FIG. 7, a large amount of deionized water may be widely provided on the substrate WF. According to some embodiments, the rotating device 325 may not be provided which is discussed with reference to FIGS. 1 to 4.

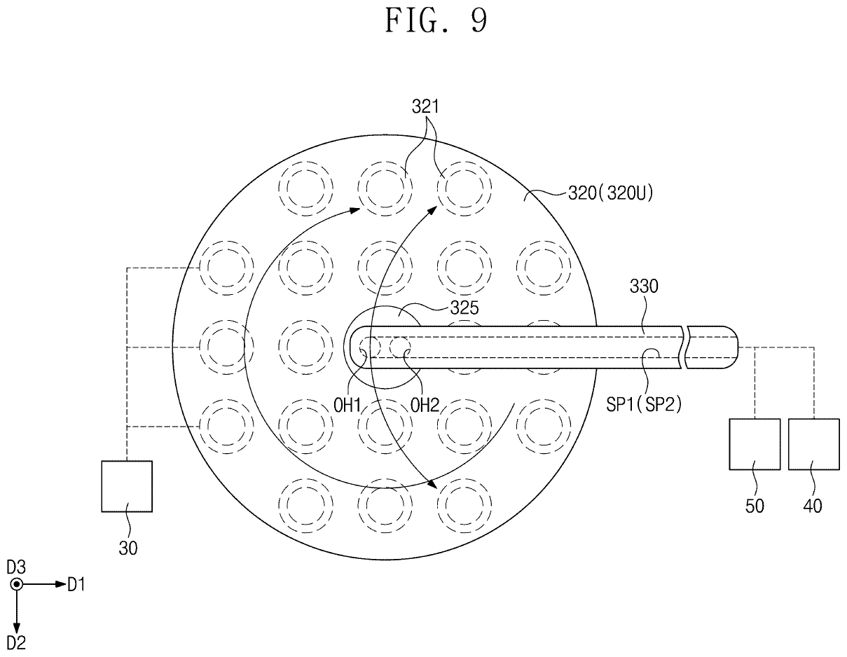

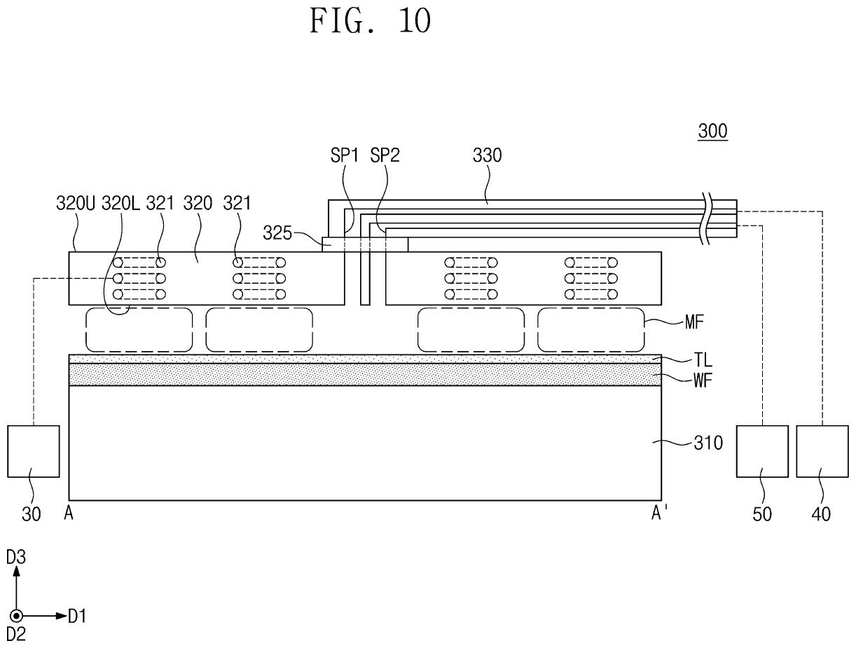

FIG. 9 illustrates a plan view showing an electromagnetic module of a substrate cleaning apparatus according to some example embodiments of the present inventive concepts. FIG. 10 illustrates a cross-sectional view taken along line A-A′ of FIG. 1, showing a substrate cleaning apparatus according to some example embodiments of the present inventive concepts.

Referring to FIGS. 9 and 10, the electromagnetic module 320 may include a plurality of electromagnetic coils 321 therein. For example, the electromagnetic coil 321 may be provided in plural in the electromagnetic module 320. The plurality of electromagnetic coils 321 may be two-dimensionally arranged in the electromagnetic module 320. For example, the plurality of electromagnetic coils 321 may be spaced apart from each other in the first direction D1 and the second direction D2.

When viewed in plan, each of the plurality of electromagnetic coils 321 may have a ring shape. In addition, each of the plurality of electromagnetic coils 321 may be provided in a spiral shape. Each of the plurality of electromagnetic coils 321 may be electrically connected to a power supply device 30. The power supply device 30 may provide current to the plurality of electromagnetic coils 321.

Each of the plurality of electromagnetic coils 321 may use the current supplied from the power supply device 30 to generate a magnetic field MF on the substrate WF. The plurality of electromagnetic coils 321 may generate a plurality of magnetic fields MF on the substrate WF. For example, each of the plurality of electromagnetic coils 321 may generate a magnetic field MF on the substrate WF. Like the plurality of electromagnetic coils 321, the plurality of magnetic fields MF may be spaced apart from each other in a horizontal direction (e.g., the first direction D1 and the second direction D2). The present inventive concepts, however, are not limited thereto, and the plurality of magnetic fields MF may partially overlap each other.

According to some embodiments, the power supply device 30 may individually supply current to each of the plurality of electromagnetic coils 321. The power supply device 30 may be provided in plural. For example, some of the plurality of electromagnetic coils 321 may be supplied with the current from the power supply device 30, thereby generating magnetic fields MF. Others of the plurality of electromagnetic coils 321 may not be supplied with the current from the power supply device 30, thereby not generating magnetic fields MF. Therefore, the magnetic fields MF may be generated only on portions of regions (e.g., central and edge regions) of the substrate WF. For example, the magnetic fields MF may be generated in defined regions (e.g., central and edge regions) of the substrate WF. Alternatively, the magnetic fields MF with different intensities may be provided on different regions of the substrate WF.

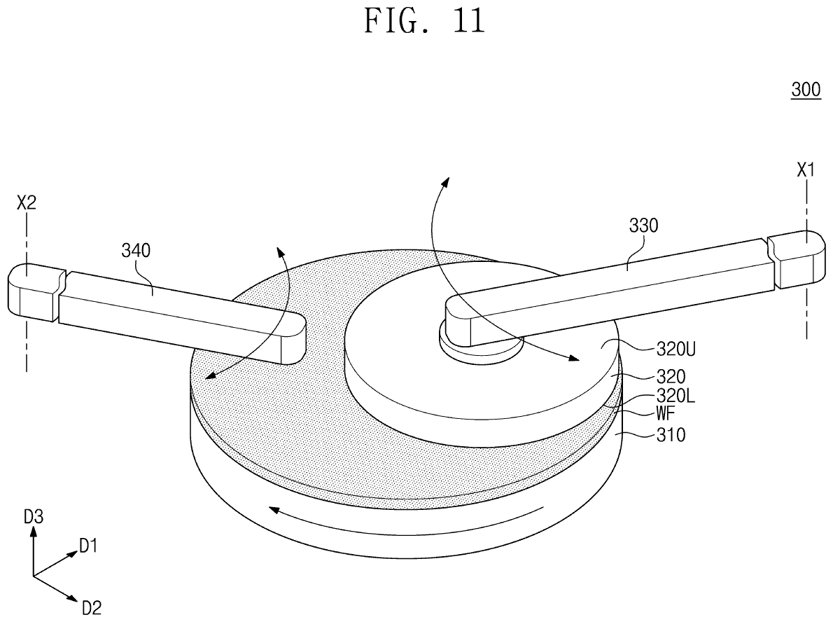

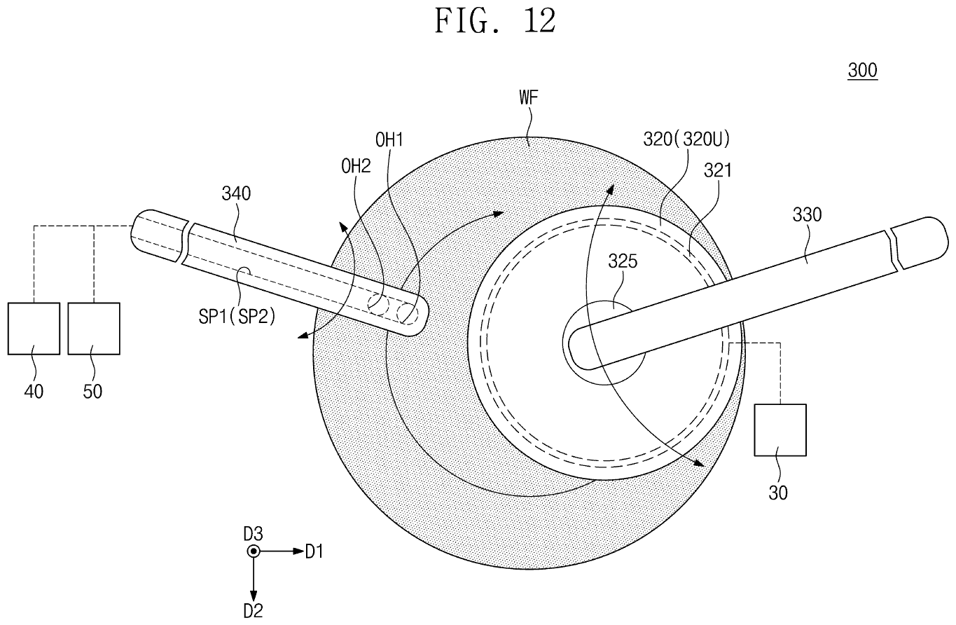

FIG. 11 illustrates a perspective view showing a substrate cleaning apparatus according to some example embodiments of the present inventive concepts. FIG. 12 illustrates a plan view showing a substrate cleaning apparatus according to some example embodiments of the present inventive concepts.

For convenience of description, explanation of components substantially the same as those discussed with reference to FIGS. 1 to 4 will be omitted, and a difference thereof will be discussed in detail.

Referring to FIGS. 11 and 12, the substrate cleaning apparatus 300 may further include a second support member 340. The second support member 340 may be disposed in an upper portion of the substrate cleaning apparatus 300 and spaced apart in the third direction D3 from the stage 310 and the substrate WF. The second support member 340 may be spaced apart from the first support member 330 in a horizontal direction.

The second support member 340 may have opposite ends in the form extended in one direction. One of the opposite ends of the second support member 340 may be adjacent to and positioned on the stage 310. A second axis X2 may penetrate the other of the opposite ends of the second support member 340. The second axis X2 may be parallel to the third direction D3. The second support member 340 may be configured to move in a horizontal direction about the second axis X2. For example, the second support member 340 may be configured to move independently of and separately from the first support member 330.

The second support member 340 may provide a first outlet OH1 and a second outlet OH2 spaced apart from each other on a bottom surface thereof. The first outlet OH1 and the second outlet OH2 may be positioned on the one, which is adjacent to the stage 310, of the opposite ends of the second support member 340. Thus, a treatment solution may be supplied through the first outlet OH1 onto the substrate WF, and deionized water may be supplied through the second outlet OH2 onto the substrate WF. In example embodiments, the configurations of the first outlet OH1 and the second outlet OH2 may be any of the configurations illustrated in FIGS. 1-6, FIG. 7, or FIG. 8.

The second support member 340 may provide a first supply line SP1 and a second supply line SP2 therein. The liquid supply device 40 and the first outlet OH1 may be connected to each other through the first supply line SP1 connected therebetween. The DIW supply device 50 and the second outlet OH2 may be connected to each other through the second supply line SP2 connected therebetween.

According to some embodiments, as discussed with reference to FIGS. 1 to 4, neither the first outlet OH1 nor the second outlet OH2 may be provided on the bottom surface 320L of the electromagnetic module 320. In addition, neither the first supply line SP1 nor the second supply line SP2 may be provided in the first support member 330. When viewed in plan, a diameter of the electromagnetic module 320 may be less than that of the stage 310.

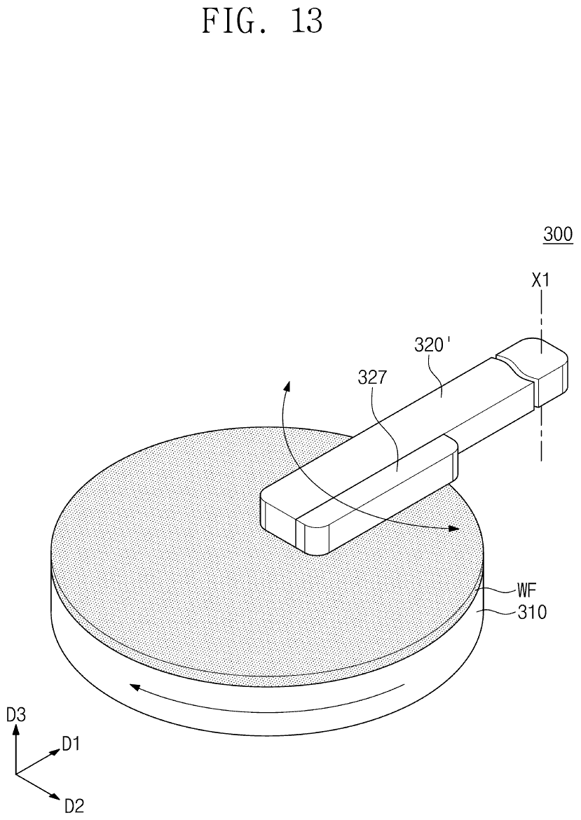

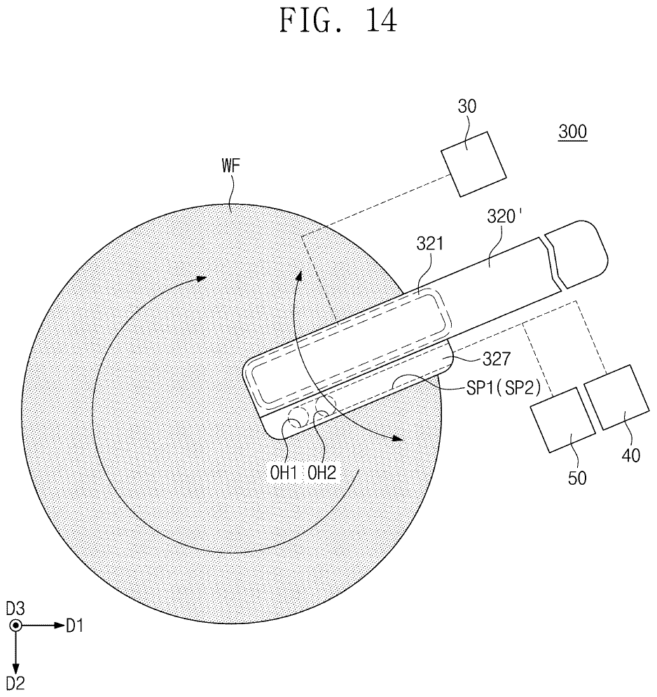

FIG. 13 illustrates a perspective view showing a substrate cleaning apparatus according to some example embodiments of the present inventive concepts. FIG. 14 illustrates a plan view showing a substrate cleaning apparatus according to some embodiments of the present inventive concepts.

For convenience of description, explanation of components substantially the same as those discussed with reference to FIGS. 1 to 4 will not be repeated, and differences thereof will be discussed in detail.

Referring to FIGS. 13 and 14, the substrate cleaning apparatus 300 may not include any of the first support member 330 and the rotating device 325 discussed with reference to FIGS. 1 to 4. The substrate cleaning apparatus 300 may further include a supply module 327 on one lateral surface of the electromagnetic module 320′. For example, the first support member 330 and the electromagnetic module 320 may be combined into a single unitary component (i.e., electromagnetic module 320′).

The electromagnetic module 320′ may have opposite ends in the form extended lengthwise in one direction. One of the opposite ends of the electromagnetic module 320′may be adjacent to and positioned on the stage 310 and the substrate WF. A first axis X1 may penetrate the other of the opposite ends of the electromagnetic module 320′. The first axis X1 may be parallel to the third direction D3. The electromagnetic module 320′ may move in a horizontal direction about the first axis X1.

The electromagnetic module 320′ may include an electromagnetic coil 321 therein. When viewed in plan, the electromagnetic coil 321 may be shaped like a square frame whose inside is opened. At least a portion of the electromagnetic coil 321 may vertically overlap the substrate WF on the stage 310. The electromagnetic coil 321 may be electrically connected to the power supply device 30 to receive current from the power supply device 30. The electromagnetic coil 321 may use the supplied current to partially generate a magnetic field on the substrate WF.

The supply module 327 may be positioned on one lateral surface of the electromagnetic module 320′, thereby being combined with the electromagnetic module 320′. The supply module 327 may be combined with the electromagnetic module 320′ to move in a horizontal direction along with the electromagnetic module 320′. The supply module 327 may have a shape that extends lengthwise in one direction. An extending length of the supply module 327 may be less than that of the electromagnetic module 320′.

The supply module 327 may provide a first outlet OH1 and a second outlet OH2 on a bottom surface thereof. The supply module 327 may provide therein a first supply line SP1 and a second supply line SP2 that extend lengthwise in one direction. The first supply line SP1 may be connected to the first outlet OH1 and the liquid supply device 40, and the second supply line SP2 may be connected to the second outlet OH2 and the DIW supply device 50. For example, the liquid supply device 40 may provide a treatment solution onto the substrate WF through the first supply line SP1 and the first outlet OH1. The DIW supply device 50 may provide deionized water onto the substrate WF through the second supply line SP2 and the second outlet OH2. In example embodiments, the configurations of the first outlet OH1 and the second outlet OH2 may be any of the configurations illustrated in FIGS. 1-6, FIG. 7, or FIG. 8.

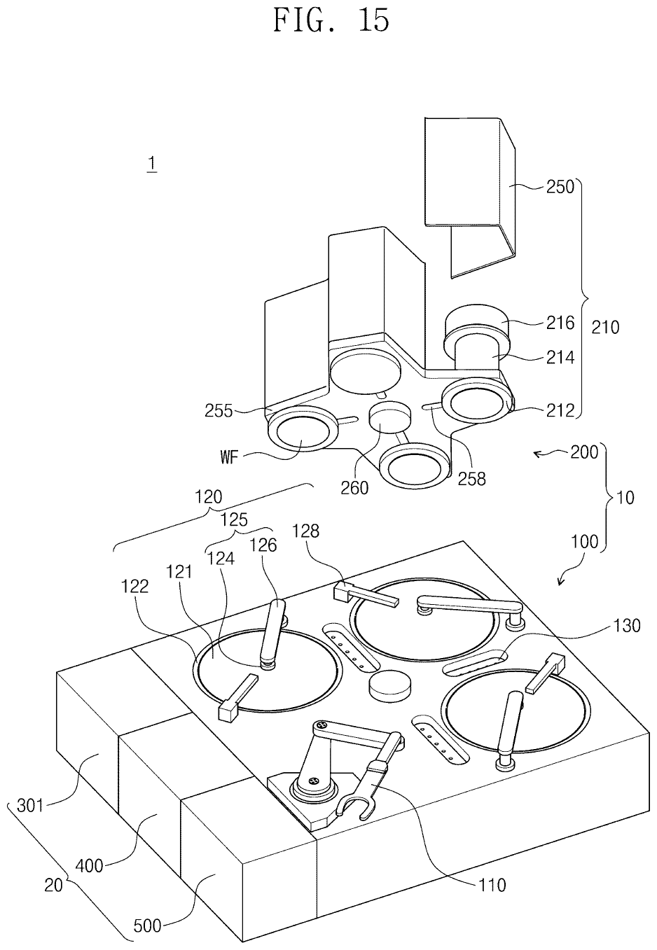

FIG. 15 illustrates a perspective view showing a substrate processing apparatus according to some example embodiments of the present inventive concepts.

Referring to FIG. 15, a substrate processing apparatus 1 may be provided. The substrate processing apparatus 1 according to some embodiments of the present inventive concepts may be a facility for chemically mechanically polish one surface of the substrate WF and cleaning the polished surface of the substrate WF. For example, semiconductor patterns may be integrated on one surface of the substrate WF. For example, the substrate processing apparatus 1 may include a polishing section 10 that polishes the one surface of the substrate WF and a cleaning section 20 that cleans the one surface of the substrate WF.

The polishing section 10 may include a lower machine 100 and a carousel 200. The lower machine 100 may include a mobile station 110, polishing stations 120, and washing stations 130.

The mobile station 110 of the polishing section 10 may transfer the substrate WF. The mobile station 110 may be positioned on substantially the same plane on which three polishing stations 120 are located. The mobile station 110 may transfer the substrate WF polished on one of the polishing stations 120 to another of the polishing stations 120. In addition, the mobile station 110 may transfer the polished substrate WF to the cleaning section 20.

Each of the polishing stations 120 may include a polishing pad 121, a platen 122, a pad conditioner 125, and a slurry supply device 128. The polishing pad 121 may be disposed on and supported by the platen 122. The platen 122 may include a driving unit. The driving unit may include a motor, driving the platen 122 to rotate. The polishing pad 121 may rotate together with the platen 122. Each of the polishing pad 121 and the platen 122 may have a disk shape. A top surface of the polishing pad 121 may contact and polish the one surface of the substrate WF. For example, the polishing pad 121 and the platen 122 may each have a diameter greater than about twice that of the substrate WF.

The pad conditioner 125 may include a conditioner head 124 and a rotating arm 126. The conditioner head 124 and the rotating arm 126 may rotate independently of each other. The rotating arm 126 may place the conditioner head 124 on the polishing pad 121, while supporting the conditioner head 124. For example, the rotating arm 126 may drive the conditioner head 124 to move in a horizontal direction on the polishing pad 121. The pad conditioner 125 may polish one surface of the polishing pad 121. The pad conditioner 125 may change a state of the polishing pad 121. For example, the pad conditioner 125 may maintain the polishing pad 121 in a constant state, and thus the substrate WF may be uniformly polished.

The slurry supply device 128 may be positioned on the polishing pad 121. The slurry supply device 128 may provide slurry onto the polishing pad 121. For example, the slurry may include a reactive agent (e.g., deionized water for oxidation polishing), abrasive particles (e.g., silicon dioxide for oxidation polishing), and a chemical reaction catalyst (e.g., potassium hydroxide for oxidation polishing). The slurry may be provided to cover a top surface of the polishing pad 121. The slurry supply device 128 may include a plurality of injection nozzles on a bottom surface thereof, but the present inventive concepts are not limited thereto.

Each of the washing stations 130 may be positioned between neighboring polishing stations 120. When the substrate WF moves between the polishing stations 120, the washing stations 130 may wash the substrate WF.

The carousel 200 may include polishing head systems 210 and a central pillar 260. The carousel 200 may be disposed on the lower machine 100. The polishing head systems 210 may be supported by the central pillar 260, and may rotate in a clockwise or counterclockwise direction about the central pillar 260. Four polishing head systems 210 may be provided, but the present inventive concepts are not limited thereto.

Each of the polishing head systems 210 may support the substrate WF. For example, three of the polishing head systems 210 may support and hold the substrate WF, pressing the substrate WF against the polishing pad 121. Thus, one surface of the substrate WF may be polished. One of the polishing head systems 210 may transfer the substrate WF onto the mobile station 110, while supporting and holding the substrate WF.

Each of the polishing head systems 210 may include a polishing head 212, spindles 214, a motor 216, and a housing 250. The polishing head 212 may independently rotate about a rotational axis thereof. The polishing head 212 may move in a horizontal direction in openings 258 provided on a support plate 255 of the housing 250. For example, the polishing head 212 may have a cylindrical shape.

The spindles 214 may be positioned between the motor 216 and the polishing head 212. The spindles 214 may connect the motor 216 to the polishing head 212. The motor 216 may cause the spindles 214 to rotate the polishing head 212.

The housing 250 may cover and prevent the spindles 214 and the motor 216 from being externally exposed. The support plate 255 of the housing 250 may outwardly expose the polishing head 212. The support plate 255 of the housing 250 may radially extend to provide four openings 258 spaced apart at about 90° from each other.

The cleaning section 20 may include a substrate cleaning module 301, a brushing part 400, and a drying part 500. The cleaning section 20 may use the polishing section 10 to remove contaminant particles present on one surface of the substrate WF. For example, the cleaning section 20 may be configured to prevent the occurrence of scratches on a surface of the substrate WF.

The substrate cleaning module 301 may use a treatment layer including a polymeric material to remove contaminant particles present on one surface of the substrate WF. The substrate cleaning module 301 may be configured such that, after the treatment layer and the contaminant particles are attached to each other, the treatment and the contaminant particles are removed from the substrate WF. For example, in order to remove contaminant particles, the substrate cleaning module 301 may use deionized water and a treatment solution that includes magnetic particles. For example, the substrate cleaning apparatus 300 discussed with reference to FIGS. 1 to 14 may be provided as one module in the substrate processing apparatus 1 composed of a plurality of modules. The substrate cleaning module 301 may be substantially the same as the substrate cleaning apparatus 300 discussed with reference to FIGS. 1 to 14.

The brushing part 400 may include a substrate cleaning brush, and the substrate cleaning brush may be used to clean one surface of the substrate WF. The brushing part 400 may use a cleaning solution and/or deionized water to clean the substrate WF. The brushing part 400 may simultaneously rotate the substrate WF and the substrate cleaning brush.

The drying part 500 may dry the substrate WF that is cleaned through the substrate cleaning module 301 and/or the brushing part 400. For example, the drying part 500 may remove a cleaning solution that remains on the surface of the substrate WF. According to some embodiments, the drying part 500 may be one of a spin dryer, an isopropyl alcohol (IPA) vapor dryer, and a Marangoni dryer. The spin dryer may be configured such that a centrifugal force due to rotation is used to dry the substrate WF. The IPA vapor dryer may dry the substrate WF by using vapor produced by heating isopropyl alcohol (IPA) as an organic solvent. The Marangoni dryer may dry the substrate WF by using a difference in surface tension of isopropyl alcohol (IPA) formed on deionized water.

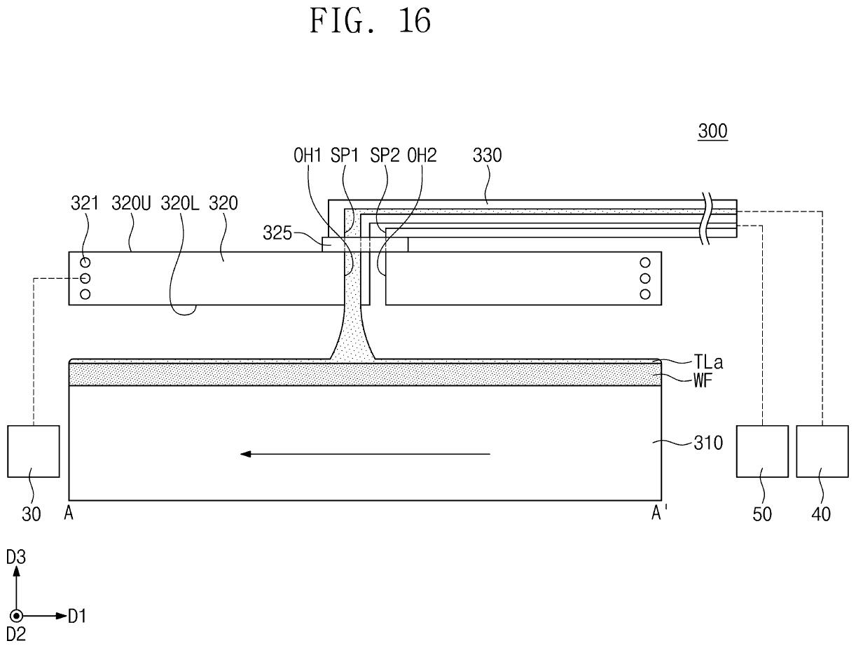

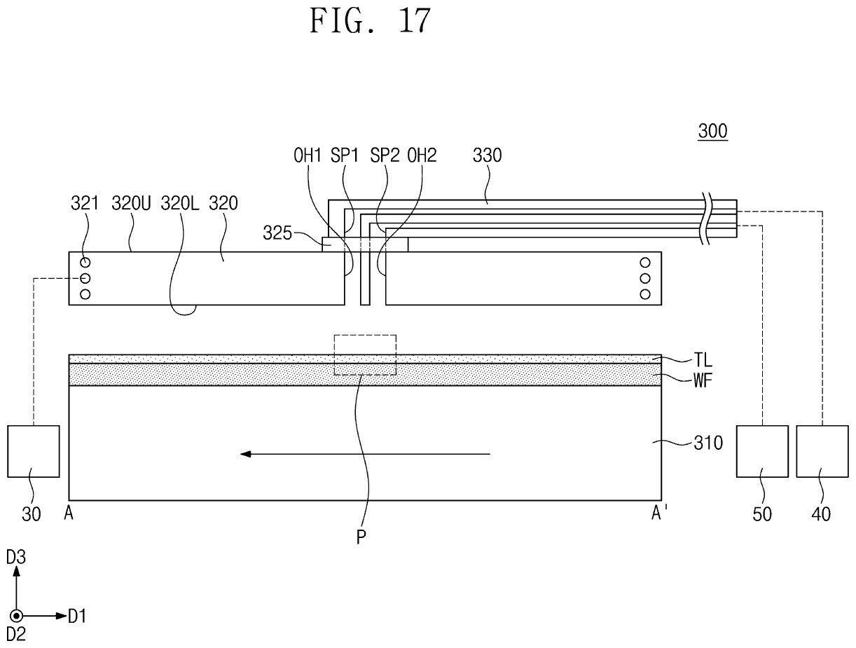

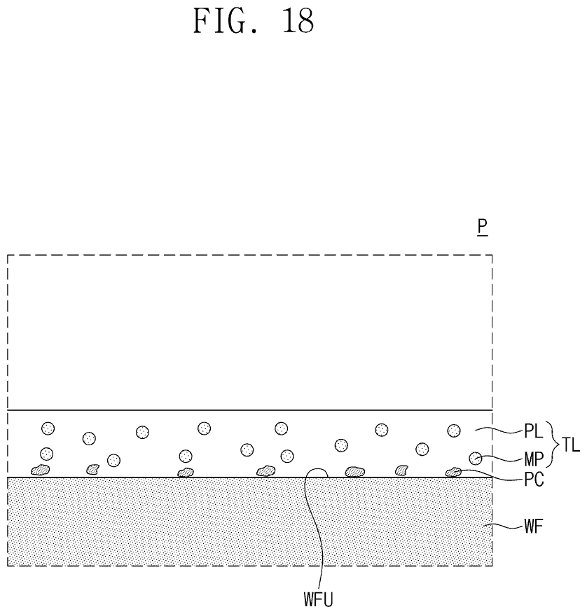

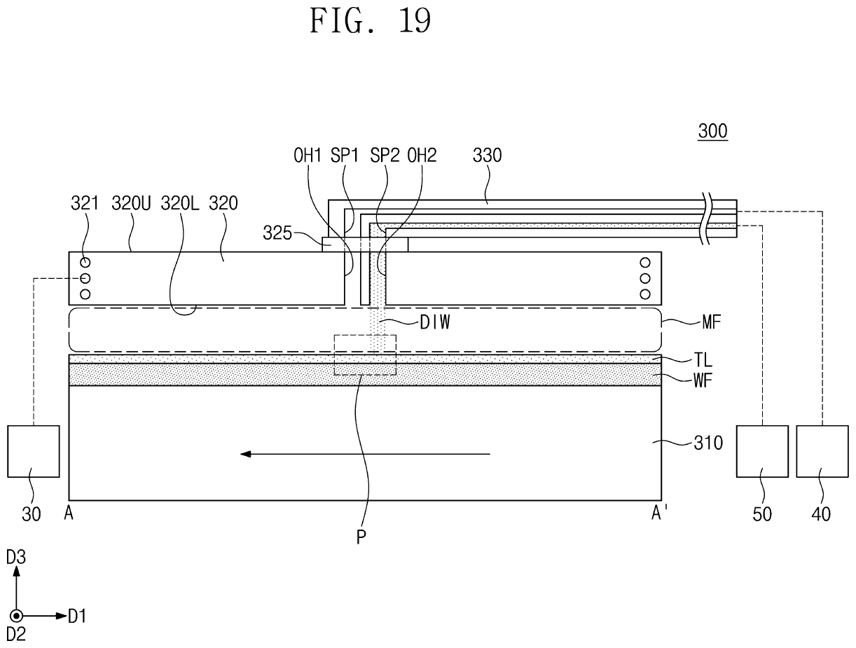

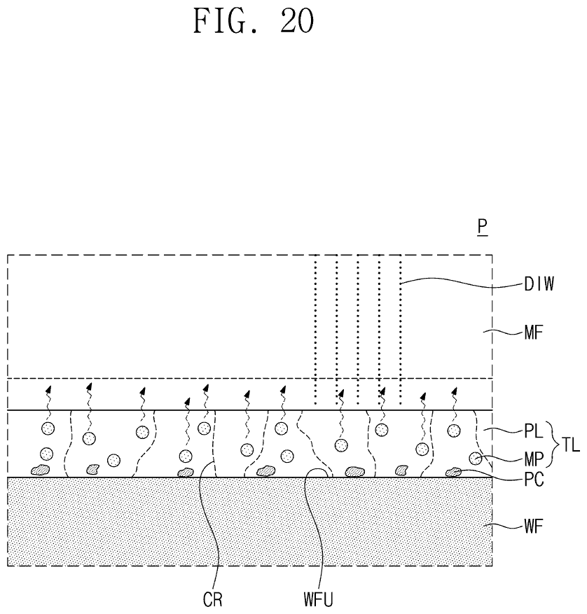

FIGS. 16 to 20 illustrate diagrams showing a substrate processing method according to some example embodiments of the present inventive concepts. FIGS. 16, 17, and 19 are diagrams taken along line A-A′ of FIG. 1. FIG. 18 shows an enlarged view showing section P of FIG. 17. FIG. 20 shows an enlarged view showing section P of FIG. 19. For convenience of description, description of components substantially the same as those discussed with reference to FIGS. 1 to 4 will not be repeated, and differences thereof will be discussed in detail.

Referring to FIG. 16, a liquid-state treatment solution TLa may be provided on the substrate WF. The providing of the treatment solution TLa on the substrate WF may be performed by the liquid supply device 40. The liquid supply device 40 may provide the treatment solution TLa on the substrate WF through the first supply line SP1 in the first support member 330 and the first outlet OH1 in the electromagnetic module 320.

According to some embodiments, the treatment solution TLa may be a polymeric material containing magnetic particles. The magnetic particles may include iron oxide. The polymeric material may include PANiCNQ or poly(aniline-co-naphthoquinone).

During the supply of the treatment solution TLa on the substrate WF, the stage 310 may rotate in a clockwise or counterclockwise direction. For example, a spin coating process may be employed to cause the treatment solution TLa to cover a surface of the substrate WF.

Referring to FIGS. 17 and 18, the liquid-state treatment solution TLa may be cured to form a solid-state treatment layer TL. The treatment layer TL may have a constant thickness to cover a top surface WFU of the substrate WF. The treatment layer TL may include a polymeric layer PL and magnetic particles MP in the polymeric layer PL. For example, the polymeric layer PL may be formed through curing of a polymeric material of the treatment solution TLa.

The treatment layer TL may cover the top surface WFU of the substrate WF, and may also cover the contaminant particles PC present on the top surface WFU of the substrate WF. The polymeric layer PL may be in contact with the contaminant particles PC, and thus the contaminant particles PC may be attached to the polymeric layer PL.

Referring to FIGS. 19 and 20, deionized water DIW may be provided on the polymeric layer PL. The providing of the deionized water DIW may be performed by the DIW supply device 50. The DIW supply device 50 may provide the deionized water DIW on the treatment layer TL through the second supply line SP2 in the first support member 330 and the second outlet OH2 in the electromagnetic module 320.

During the supply of the deionized water DIW, the electromagnetic coil 321 in the electromagnetic module 320 may be supplied with current from the power supply device 30. The electromagnetic coil 321 may use the supplied current to generate the magnetic field MF on the substrate WF. For example, the providing of the deionized water DIW and the generation of the magnetic field MF may be performed simultaneously.

The deionized water DIW may be provided at high pressures on the treatment layer TL. For example, the deionized water DIW may be provided at a pressure greater than that of the treatment solution TLa. The high pressure of the deionized water DIW may lead to the occurrence of crack CR in the treatment layer TL. For example, the deionized water DIW may be one of causes that induce the crack CR of the treatment layer TL.

The movement of the magnetic particles MP may be achieved by the magnetic field MF generated from the electromagnetic coil 321 of the electromagnetic module 320. For example, the magnetic particles MP may have movement away from the top surface WFU of the substrate WF. In addition, the magnetic particles MP may have an oscillating movement in a horizontal direction. The movement in vertical and horizontal directions of each of the magnetic particles MP may be another one of causes that induce the crack CR of the treatment layer TL.

As a result, the crack CR inside the treatment layer TL may be formed due to the movement of the magnetic particles MP caused by the magnetic field MF and the deionized water DIW provided on the substrate WF. In a substrate processing method according to some embodiments of the present inventive concepts, an internal cause (e.g., movement of the magnetic particles MP) and an external cause (e.g., pressure of the deionized water DIW) may be simultaneously provided to facilitate the occurrence of the crack CR of the treatment layer TL. Thus, the treatment layer TL on the substrate WF may be cracked and easily removed from the substrate WF. Accordingly, the contaminant particles PC on the top surface WFU of the substrate WF may be removed along with the treatment layer TL.

A substrate cleaning apparatus and a substrate processing apparatus including the same according to some embodiments of the present inventive concepts may simultaneously provide an internal cause (e.g., movement of magnetic particles) and an external cause (e.g., pressure of deionized water) to produce cracks in treatment layer on a substrate. Thus, the treatment layer may be easily cracked and removed from the substrate. Accordingly, contaminant particles on a surface of the substrate may be removed along with the treatment layer.

In addition, the treatment layer (or a treatment solution) may include a polymer having magnetic properties, and a magnetic field on the substrate may allow the contaminant particles to have magnetic properties. Thus, a magnetic force may be provided between the contaminant particles and the treatment layer, thereby increasing adhesion therebetween. Accordingly, the contaminant particles on a surface of the substrate may be removed completely.

Although the present invention has been described in connection with the embodiments of the present inventive concepts illustrated in the accompanying drawings, it will be understood to those skilled in the art that various changes and modifications may be made without departing from the technical spirit and scope of the present inventive concepts. It therefore will be understood that the embodiments described above are just illustrative but not limitative in all aspects.

What is claimed is:

1. A substrate cleaning apparatus, comprising:
a stage that supports a substrate; and
an electromagnetic module on the stage,
wherein the electromagnetic module comprises an electromagnetic coil in the electromagnetic module,
wherein the electromagnetic module provides a first outlet and a second outlet on a bottom surface of the electromagnetic module, and
wherein the electromagnetic coil is configured to generate a magnetic field on the substrate.

2. The substrate cleaning apparatus of claim 1, wherein a treatment solution is configured to be provided through the first outlet onto the substrate.

3. The substrate cleaning apparatus of claim 2,
wherein the treatment solution comprises a polymeric material that contains a magnetic material, and
wherein the magnetic material has movement caused by the magnetic field.

4. The substrate cleaning apparatus of claim 3,
wherein the magnetic material comprises iron oxide, and
wherein the polymeric material comprises PANiCNQ.

5. The substrate cleaning apparatus of claim 1, wherein deionized water is configured to be provided through the second outlet onto the substrate.

6. The substrate cleaning apparatus of claim 1, wherein the second outlet is provided in plural.

7. The substrate cleaning apparatus of claim 1, wherein the second outlet has a shape that extends lengthwise in one direction.

8. The substrate cleaning apparatus of claim 1,
wherein the electromagnetic coil is a plurality of electromagnetic coils, and
wherein the plurality of electromagnetic coils are two-dimensionally arranged.

9. The substrate cleaning apparatus of claim 1, wherein the stage further comprises a lower electromagnetic coil in the stage.

10. The substrate cleaning apparatus of claim 1, wherein the electromagnetic module is configured to rotate while moving in a horizontal direction parallel to a top surface of the substrate.

11. A substrate cleaning apparatus, comprising:
a stage that supports a substrate;
an electromagnetic module on the stage;
a liquid supply device that provides a treatment solution; and
a deionized water supply device that provides deionized water,
wherein the electromagnetic module is configured to generate a magnetic field on the substrate, and
wherein the treatment solution comprises a magnetic material that has movement caused by the magnetic field.

12. The substrate cleaning apparatus of claim 11,
wherein the electromagnetic module provides a first outlet and a second outlet on a bottom surface of the electromagnetic module,
wherein the treatment solution is configured to be provided through the first outlet onto the substrate, and
wherein the deionized water is configured to be provided through the second outlet onto the substrate.

13. The substrate cleaning apparatus of claim 11, further comprising:
a first support member combined with the electromagnetic module; and
a second support member spaced apart from the first support member,
wherein the second support member provides a first outlet and a second outlet on a bottom surface of the second support member, and
wherein the first outlet is connected to the liquid supply device, and the second outlet is connected to the deionized water supply device.

14. The substrate cleaning apparatus of claim 11,
wherein the electromagnetic module comprises an electromagnetic coil in the electromagnetic module,
wherein the stage comprises a lower electromagnetic coil in the stage, and
wherein the stage is configured to rotate the substrate and the lower electromagnetic coil.

15. The substrate cleaning apparatus of claim 11,
wherein the electromagnetic module comprises a plurality of electromagnetic coils spaced apart from each other, and
wherein the plurality of electromagnetic coils are configured to generate magnetic fields that are independent of each other.

16. A substrate processing apparatus, comprising:
a polishing section that uses a polishing pad to polish one surface of a substrate; and
a cleaning section that cleans the substrate,
wherein the cleaning section comprises:
a stage that supports the substrate;
an electromagnetic module on the stage;
a liquid supply device that provides a treatment solution onto the substrate; and
a deionized water supply device that provides deionized water onto the substrate, and
wherein the electromagnetic module is configured to generate a magnetic field on the substrate.

17. The substrate processing apparatus of claim 16,
wherein the electromagnetic module provides a first outlet and a second outlet on a bottom surface of the electromagnetic module, and
wherein the first outlet is connected to the liquid supply device, and the second outlet is connected to the deionized water supply device.

18. The substrate processing apparatus of claim 16,
wherein the electromagnetic module comprises an electromagnetic coil in the electromagnetic module, and
wherein the stage comprises a lower electromagnetic coil in the stage.

19. The substrate processing apparatus of claim 16,
wherein the treatment solution comprises a polymeric material that contains a magnet material having movement caused by the magnetic field, and
wherein the polymeric material comprises PANiCNQ.

20. The substrate processing apparatus of claim 16,
wherein the electromagnetic module comprises a plurality of electromagnetic coils in the electromagnetic module, and
wherein the plurality of electromagnetic coils are spaced apart from each other and two-dimensionally arranged.
